(19) United States
(12) Patent Application Publication
(10) Pub. No.: US 2025/0022697 A1
(43) Pub. Date: Jan. 16, 2025

(54) PLASMA SYSTEM HAVING RESIDENCE TIME TUNING ASSEMBLY

(71) Applicant: Applied Materials, Inc., Santa Clara, CA (US)

(72) Inventors: Costel BILOIU, Rockport, MA (US); David MORRELL, Wakefield, MA (US); Solomon Belangedi BASAME, Middleton, MA (US); Adam CALKINS, Newmarket, NH (US); Kevin Richard VERRIER, Hampton, NH (US)

(73) Assignee: Applied Materials, Inc., Santa Clara, CA (US)

(21) Appl. No.: 18/220,163

(22) Filed: Jul. 10, 2023

(51) Int. Cl. H01J 37/32

(52) U.S. Cl. CPC H01J 37/3299; H01J 37/32449; H01J 37/32834; H01J 2237/334

(57) ABSTRACT

A plasma processing apparatus. The plasma processing apparatus may include a plasma chamber, to define a plasma therein, and an extraction aperture, arranged along a first side of the plasma chamber, the extraction aperture to define an ion beam extracted therethrough. The plasma processing apparatus may further include a residence time tuning assembly, coupled to a portion of the plasma chamber, different from the first side, wherein the residence time tuning assembly comprises a pumping duct, connected to the plasma chamber on a first end, and defining a pumping path for extracting a gaseous species directly from the plasma chamber, separately from the extraction aperture.

### FIELD OF THE DISCLOSURE

The disclosure relates generally to plasma processing apparatus, and more particularly to plasma based ion sources and related processing apparatus.

### BACKGROUND OF THE DISCLOSURE

In the present day, plasmas are used to process semiconductor substrates to make integrated electronic circuitries. In such applications ions are involved in substrate etching, ion implantation, thin films deposition, and other processes. Some processing apparatus employ a plasma chamber that generates a plasma to act as an ion source for substrate processing. An ion beam may be extracted through an extraction assembly and directed to a substrate in an processing chamber located adjacent to plasma chamber. Depending on how the energy is delivered to the working gas, plasma in the ion source may be generated in various ways such as rf excitation, dc, or microwave.

According to designs of processing apparatus having a plasma chamber or ion source that is separate from a process chamber, recent designs may include an ion extraction assembly where an extraction plate is provided that includes an extraction aperture that defines an ion beam, when a bias is applied between the plasma chamber and the process chamber, such as a substrate plate located in the process chamber. The gas used to generate the plasma may be admitted into the plasma chamber through one or more conduits. Moreover, in addition to the ion beam, other gaseous species, including excited neutrals (both atoms and molecules) and unexcited gas, travel from the plasma chamber into the process chamber through the extraction aperture. Gaseous species are then evacuated from the processing system via pumping ports and external pumps connected to the process chamber. Accordingly, outward flow of gas from the ion source or plasma chamber takes place through the same structure(s) that are used to extract ions or an ion beam from the ion source/plasma chamber.

In order to generate more chemically active neutral and ionic species (known as radicals), increasing residence time of gaseous species in the plasma chamber is needed. However, too long residence time may result in excessive fractionation of the parent monomer that is fed into the plasma chamber. This circumstance reduces the production of polymeric species that are needed to protect trenches' sidewalls. Therefore, a careful tuning of the residence time is needed. The residence time is proportional to the gas pressure in the plasma chamber and inversely proportional to the flow rate of gas. In known systems, a substrate platen may be placed adjacent to the extraction aperture, such as within several millimeters or a few centimeters of the extraction aperture. In order to vary the vacuum conductance and therefore vary the residence time, the substrate platen may be moved to vary the orthogonal distance between extraction plate and substrate platen, the so-called Z-gap. However, variation of the Z-gap also changes the electrostatic field adjacent the extraction aperture, and therefore affects the characteristics of an extracted ion beam. Changes in electrostatic field may be compensated by adjusting correspondingly the extraction voltage, but this adjustment leads to a change of the ion energy. Thus, according to known designs of plasma processing systems using a plasma chamber with an extraction aperture, varying residence time may not be accomplished independently of varying other process features, such as ion beam properties.

With respect to these and other considerations the present disclosure is provided.

### BRIEF SUMMARY

In one embodiment, a plasma processing apparatus is provided, including a plasma chamber, to define a plasma therein, and an extraction aperture, arranged along a first side of the plasma chamber, where the extraction aperture is arranged to define an ion beam extracted therethrough. The plasma processing apparatus may also include a residence time tuning assembly, coupled to a portion of the plasma chamber, different from the first side. The residence time tuning assembly may include a pumping duct, connected to the plasma chamber on a first end, and defining a pumping path for extracting a gaseous species directly from the plasma chamber, separately from the extraction aperture.

In another embodiment, a plasma processing system is provided, including a plasma chamber, to define a plasma therein, and a process chamber, arranged along a side of the plasma chamber. The plasma processing system may include an extraction aperture, arranged between the plasma chamber, and process chamber, where the extraction aperture is arranged to define an ion beam extracted therethrough. The plasma processing system may also include a residence time tuning assembly, coupled to a portion of the plasma chamber, different from the first side. The residence time tuning assembly may include a pumping duct, connected to the plasma chamber on a first end, and defining a pumping path for extracting a gaseous species directly from the plasma chamber, separately from the extraction aperture.

In a further embodiment, a method of operating an ion source is provided, including forming a plasma in a plasma chamber of the ion source using gaseous species. The method may include extracting an ion beam through an extraction aperture disposed along a side of the ion source. The method may include pumping at least a portion of the gaseous species from the plasma chamber using a residence time tuning assembly that comprises a pumping duct, connected to the plasma chamber on a first end, and defines a pumping path for extracting the gaseous species directly from the plasma chamber, separately from the extraction aperture.

### BRIEF DESCRIPTION OF THE DRAWINGS

FIG. 1A shows a side view of a processing system, according to embodiments of the disclosure;

FIG. 1B illustrates the processing system of FIG. 1A in operation;

FIG. 2A shows a variant of the residence time tuning assembly of FIG. 1A;

FIG. 2B shows a more specific example of the residence time tuning assembly of FIG. 2A;

FIG. 3A shows a plasma processing apparatus, including a variant of the residence time tuning assembly of FIG. 1A;

FIG. 3B shows a specific example of the residence time tuning assembly of FIG. 3A;

FIG. 4 shows a plasma processing apparatus, including another variant of the residence time tuning assembly of FIG. 1A;

FIG. 5A and FIG. 5B illustrate an isometric view and side view, respectively of a plasma processing apparatus that includes a different variant of the residence time tuning assembly of FIG. 1A;

FIG. 6A and FIG. 6B show side views of a reference processing apparatus and a processing apparatus arranged according to embodiments of the disclosure, respectively;

FIG. 6C and FIG. 6D show the apparatus of FIG. 6A and FIG. 6B, respectively, including the gas streamlines within the process chamber;

FIG. 7A and FIG. 7B present graphs depicting computer simulations of gas species path length and time spent in a plasma chamber for a known plasma chamber and a plasma chamber pumped with a residence time tuning assembly, respectively;

FIG. 8A shows a graph that depicts plasma chamber pressure as a function of valve opening using a residence time tuning assembly according to some embodiments;

FIG. 8B shows the dependency of the amount of gas pumped through the residence time tuning assembly, as a function of valve opening percent;

FIG. 8C shows a graph depicting beam current as a function of valve opening for a valve of a residence time tuning assembly, according to embodiments of the disclosure;

FIG. 8D shows a graph depicting beam uniformity as a function of valve opening for a valve of a residence time tuning assembly, according to embodiments of the disclosure;

FIG. 9 shows variation of the gas pressure in a plasma chamber as a function of time during scanning of a substrate in an adjacent process chamber, for the cases when the plasma chamber is pumped solely through an extraction aperture and when the plasma chamber is additionally evacuated through a pumping port of a residence time tuning assembly; and

FIG. 10 depicts an exemplary process flow.

The drawings are not necessarily to scale. The drawings are merely representations, not intended to portray specific parameters of the disclosure. The drawings are intended to depict exemplary embodiments of the disclosure, and therefore are not be considered as limiting in scope. In the drawings, like numbering represents like elements.

### DETAILED DESCRIPTION

An apparatus, system and method in accordance with the present disclosure will now be described more fully hereinafter with reference to the accompanying drawings, where embodiments of the system and method are shown. The system and method may be embodied in many different forms and are not be construed as being limited to the embodiments set forth herein. Instead, these embodiments are provided so this disclosure will be thorough and complete, and will fully convey the scope of the system and method to those skilled in the art.

Terms such as “top,” “bottom,” “upper,” “lower,” “vertical,” “horizontal,” “lateral,” and “longitudinal” may be used herein to describe the relative placement and orientation of these components and their constituent parts, with respect to the geometry and orientation of a component of a semiconductor manufacturing device as appearing in the figures. The terminology may include the words specifically mentioned, derivatives thereof, and words of similar import.

As used herein, an element or operation recited in the singular and proceeded with the word “a” or “an” are understood as potentially including plural elements or operations as well. Furthermore, references to “one embodiment” of the present disclosure are not intended to be interpreted as precluding the existence of additional embodiments also incorporating the recited features.

Provided herein are apparatus for improved operation of ion sources and related systems that are used to Process substrates.

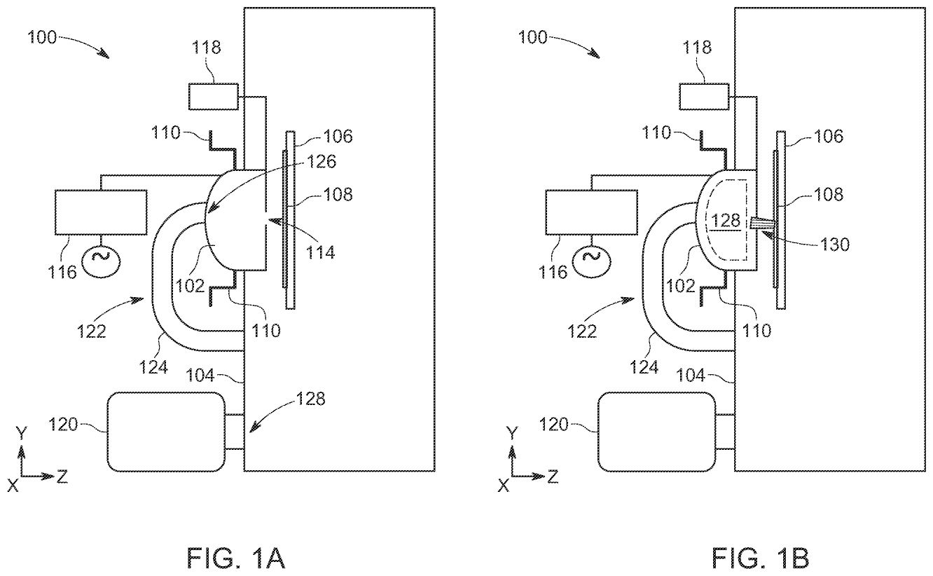

Turning to the figures, FIG. 1A shows a side view of a processing system 100, according to embodiments of the disclosure. The processing system 100 comprises of a plasma chamber 102 that acts as an ion source, as well as a process chamber 104, arranged along a side of the plasma chamber 102. The processing system 100 further includes an extraction aperture 114, arranged between the plasma chamber 102 and the process chamber 104. As shown in FIG. 1B, when a plasma 128 is formed in the plasma chamber 102, the extraction aperture 114 may define an ion beam 130 extracted therethrough. During operation, gaseous chemical species may be injected into the plasma chamber 102 via gas lines 110, where the species may be any suitable combination of inert gas and/or chemically active gas in atomic or molecular form. A plasma power assembly 116 may be provided to couple power into the plasma chamber 102. In various non-limiting embodiments, the plasma power assembly may include any suitable combination of components to generate a radio frequency (RF) plasma (a capacitively coupled plasma, inductively coupled plasma, helicon plasma), microwave plasma (an electron cyclotron resonance (ECR) plasma), or other known plasma.

During operation, an ion beam 130 may be generated, using, for example, bias supply 118 to apply a voltage between plasma chamber 102 and a substrate platen 106. When an ion beam 130 is formed, the ion beam 130 may be directed through the aperture 114 to a substrate 108, provided on the substrate platen 106 that is located in the process chamber 104. A system vacuum pump 120 is connected to the process chamber 104 to evacuate gaseous species from the process chamber 104, such as species derived from ions, neutrals, and other gas that exits the plasma chamber 102 through the extraction aperture 114 or species formed as a result of interaction with the substrate material. As an example, pressure within the plasma chamber during operation may range between 1 mTorr and 30 mTorr in some non-limiting embodiments, while gas pressure within the process chamber may range between 0.01 mTorr and few mTorr. In particular embodiments, the plasma chamber 102 and process chamber 104 may be pumped by the system vacuum pump 120 that represents one or more pumps, such as turbomolecular pumps, attached to the process chamber 104. During substrate processing using ions extracted from the plasma chamber 102, the pressure in the bulk of the process chamber 104, outside of the zone between substrate platen 106 and plasma chamber 102, may be maintained between 10⁻⁴ Torr-10⁻⁵ Torr.

In various embodiments, the substrate platen 106 may be movable along various directions, including along the Z-axis of the Cartesian coordinate system shown. In this manner, the Z-gap may be altered, which change may result in changes in the flow rate of gaseous species out of the plasma chamber 102, and resulting changes in the local gas pressure near the substrate 108. At the same time, the beam characteristics of ion beam 130 may be altered as a result of changes in the Z-gap.

As further shown in FIG. 1A, the system 100 may include a residence time tuning assembly 122 that is connected to the plasma chamber 102. The residence time tuning assembly 122 may be embodied as a pumping duct 124 that has a near end 126, including an aperture at the plasma chamber 102. In this embodiment, the residence time tuning assembly 122 has a pumping duct 124 that is directly connected to the process chamber 104 on a second end 129. Thus, in the configuration of FIG. 1A, using the system vacuum pump 120, gaseous species within plasma chamber 102 may be pumped into process chamber 104 via extraction assembly 114, as well as residence time tuning assembly 122. Moreover, gaseous species provided into plasma chamber 102 may be evacuated from the process chamber 104 using the system vacuum pump 120. As detailed in the embodiments to follow, the residence time tuning assembly 122, in various embodiments, may be used to independently control properties of the system 100, including properties related to the residence time of gaseous species within the plasma chamber 102. Because vacuum conductance is limited by the smallest duct cross section, according to various non-limiting embodiments, the vacuum ducts diameters may be chosen to maximize vacuum pumping but to match standard dimensions of vacuum hardware available on the market (such as ISO 80 or ISO 100, which diameters may be 3″ and 4″, respectively).

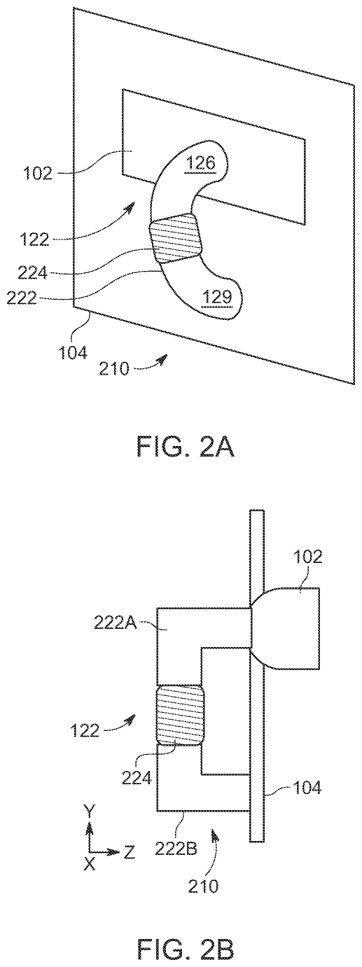

Turning to FIG. 2A there is shown a plasma processing apparatus 210 that includes a variant of the residence time tuning assembly 122, including a pumping duct 222, and a bellows 224, arranged along a portion of the pumping duct 222. FIG. 2B shows a specific example of the residence time tuning assembly 122 of FIG. 2A. In this example, the pumping duct 222 includes a first elbow portion 222a, directly connected to the plasma chamber 102, a bellows 224, connected to the first elbow portion 222a, and a second elbow portion 222b, connected to the bellows 224 and to the process chamber 104. The role of the bellows 224 is to make the joint formed by the pumping duct 122 flexible and to mitigate slight mechanical misalignments.

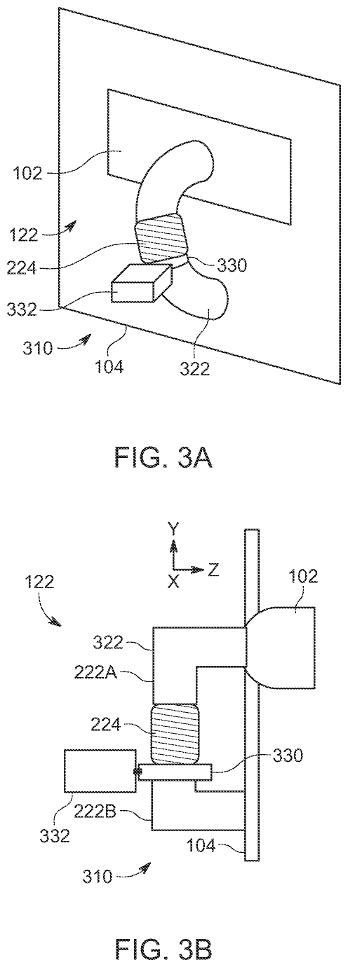

Turning to FIG. 3A there is shown a plasma processing apparatus 310, including a variant of the residence time tuning assembly 122, including a pumping duct 322, a bellows 224, arranged along a portion of the pumping duct 322. FIG. 3B shows a specific example of the residence time tuning assembly 122 of FIG. 3A. In this example, in addition to the aforementioned components of the embodiment of FIG. 2A, a valve 330 is provided, arranged between a first end of the pumping duct 322 and a second end of the pumping duct 322. The valve 330 is connected to a valve controller 332 that is arranged to vary gas pressure in the plasma chamber by adjusting the opening of the valve 330. Results of the adjustment of the valve 330 are detailed with respect to various figures to follow.

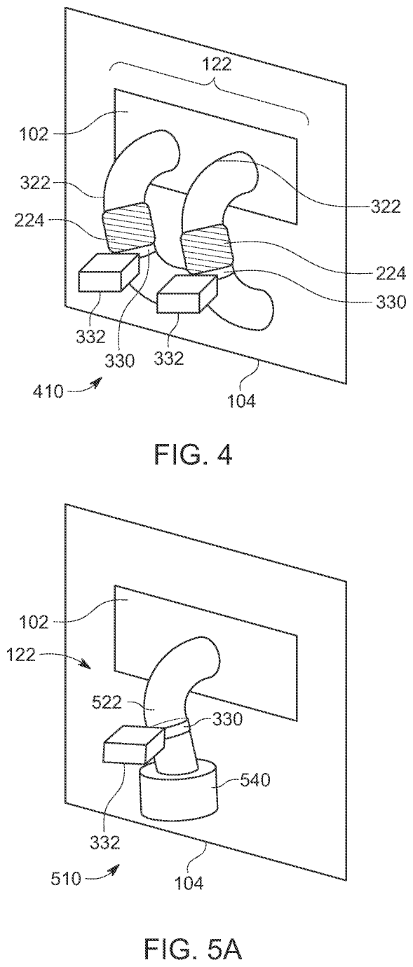

Turning to FIG. 4 there is shown a plasma processing apparatus 410, including another variant of the residence time tuning assembly 122. In this variant, the residence time tuning assembly 122 includes a pair of pumping ducts, each pumping duct being equipped with a valve 330 and valve controller 332. The leftmost of the pumping ducts 322 defines a first pumping path, while the rightmost of the pumping ducts 322 defines a second pumping path. This configuration may double the pumping conductance as opposed to the embodiment of FIG. 3 for applications where greater vacuum conductance from the plasma chamber 102 is called for.

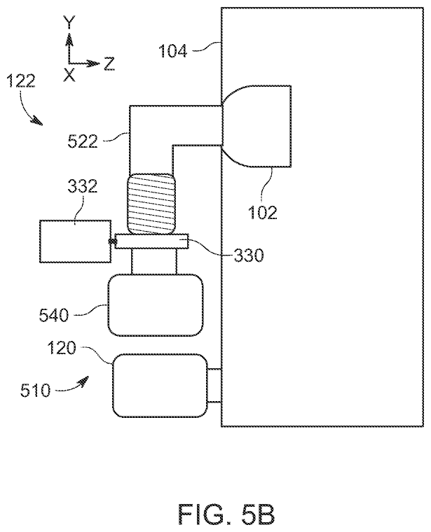

Turning to FIG. 5A and FIG. 5B there are shown an isometric view and side view, respectively of a plasma processing apparatus 510 that includes a different variant of the residence time tuning assembly 122. In this case, a back pump 540 is connected to a second end of a pumping duct 522, opposite the end of pumping duct 522 that is connected to the plasma chamber 102. The back pump provides extra direct pumping of the plasma chamber 102 that is decoupled from pumping of gas through the system vacuum pump 120. For example, in one embodiment, the back pump 540 may be a dedicated turbomolecular pump that is used to pump directly just the plasma chamber 102.

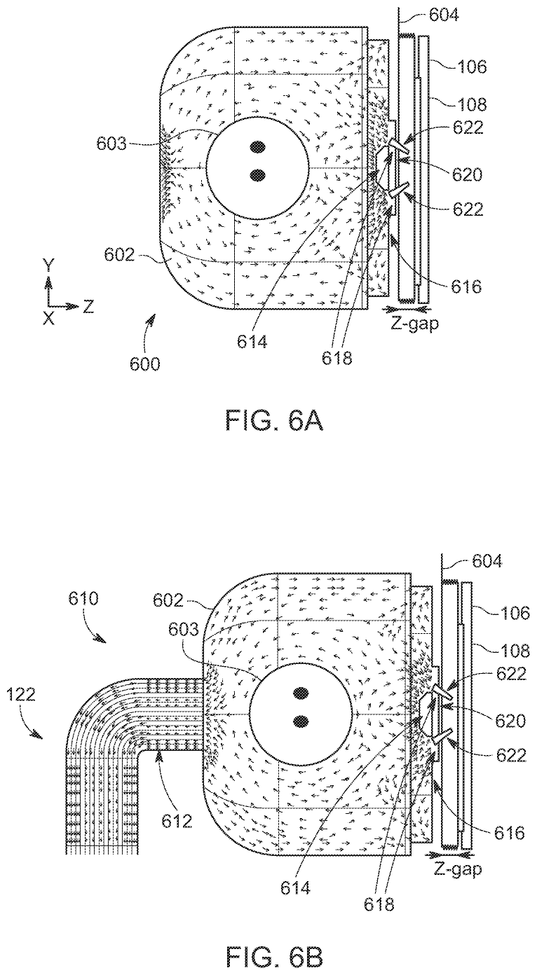

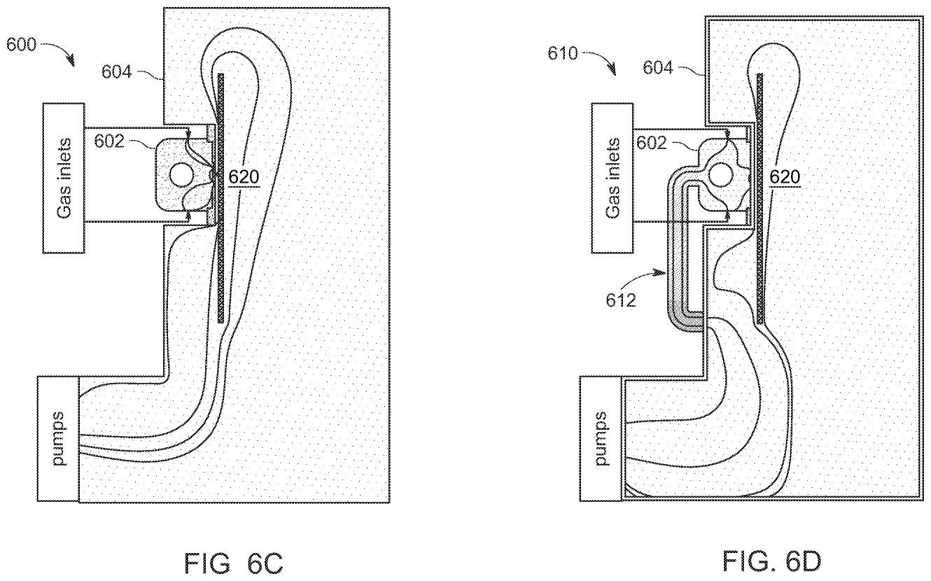

Turning to FIG. 6A and FIG. 6B there are shown side views of a reference processing apparatus 600 and a processing apparatus 610, according to embodiments of the disclosure. In the reference processing apparatus 600 and processing apparatus 610, a plasma chamber 602 is provided, which chamber includes an internal ICP antenna assembly 603, to ignite a plasma within the plasma chamber 602. The plasma chamber 602 is provided with an extraction plate 616 that defines an extraction aperture 620, for extracting an ion beam therethrough. A beam blocker 614 is provided in the plasma chamber 602 near the extraction aperture 620 in a manner that defines a pair of extraction slits 618, where the extraction slits may define an ion beam as a pair of angled ion beamlets 622.

In the reference processing apparatus 600 evacuation of gaseous species from plasma chamber 602 takes place solely through the extraction aperture 620. In FIG. 6A and FIG. 6B there is also shown a 2D map based upon a simulation of gas flow, superimposed on the plasma chamber 602. In the reference processing apparatus 600, all the gas molecules are pumped away through the extraction slits 618. In the case of processing apparatus 610, the gas pumping is divided: some gas species are pumped through the extraction slits 618 and some gas species are pumped through the residence time tuning assembly 122, in this case embodied as a pumping port 612, attached to the plasma chamber 602 at a location opposite to the extraction aperture 620.

Turning to FIG. 6C there is shown another side view of the reference processing apparatus 600, including flow paths of gaseous species from inlets in plasma chamber 602, through extraction aperture 620, and through process chamber 604 to external pumps.

Turning to FIG. 6D there is shown another side view of the processing apparatus 610, including process chamber 604. Superimposed on the side view are flow paths of gaseous species being evacuated to external pumps by the pumping port 612 and by the extraction aperture 620. The lighter shading within the plasma chamber 602 indicates a relatively higher gas pressure within plasma chamber 602 as compared to the gas pressure in process chamber 604. The gas pressure also gradually drops within the pumping port 612 as illustrated.

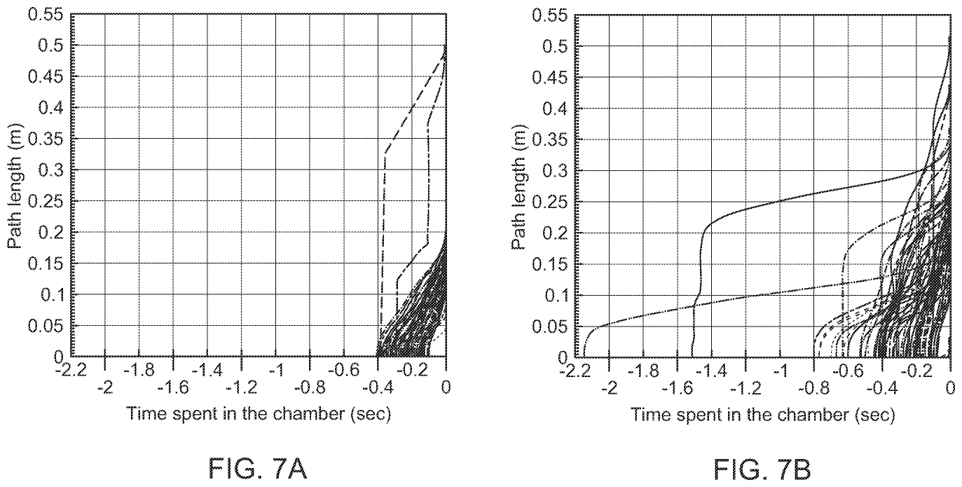

To illustrate the effect of a residence time tuning assembly 122, as depicted in the various aforementioned embodiments, FIG. 7A and FIG. 7B present graphs depicting computer simulations of path length and time spent in a plasma chamber for various simulations of a gas molecule. The graphs thus present an aggregate of numerous possible lifetime residence time outcomes for a gas molecule. In FIG. 7A a plasma chamber is provided without the residence time tuning assembly, while in FIG. 7B a residence time tuning assembly is coupled to the plasma chamber.

In the convention used in FIG. 7A and FIG. 7B, residence time is inferred from the length of the gaseous species path in the plasma chamber going backward, from the extraction slit to the gas inlet so that negative times appear along the abscissa. Qualitatively, the residence time t is the time spent by a molecule in the chamber since its injection until it is pumped away. Mathematically it can be written as

$$t = V / Q \qquad ( 1 )$$

where Vis the chamber volume and Q the flow rate. If Vis expressed in cm³ and Q in sccm, then residence time will result in minutes. However, residence time depends also on the gas flow regime (turbulent, laminar, transitional or molecular) which regime is dictated by the mean free path (gas pressure), chamber dimensions (chamber geometry), and gas inlets and outlets locations. In accordance with embodiments of the disclosure, a relatively wider residence time variation range may be generated by use of a residence time tuning assembly 122. At the lower end relatively greater production of radicals and ions are favored because collision probability of a gas molecule increases, and at the higher end formation of polymeric films is favored. Generally, residence time can be tuned by varying the plasma chamber pressure while maintaining constant the gas flow rate. However, as evidenced by the simulation of FIG. 7A and FIG. 7B, residence time is a statistical quantity, and can be more precisely calculated from the statistics of the times spent by the molecules in the plasma chamber. Considering all gas species passing through the extraction slits provided and calculating backwards in time the respective paths of the gas species, a range of residence times can be inferred from the graphs. For the case of no back pumping in FIG. 7A, the residence time is between 100 msec and 400 msec. For the same gas flow rate, in the case of back pumping using a residence time tuning assembly as detailed above, although there are a few gas species that spend even more than 2 sec in the plasma chamber, most of the residence times fall between 100 msec and 800 msec, an increase of the residence time of 400 msec for many gas species with respect to the scenario without residence time tuning assembly as shown in FIG. 7A.

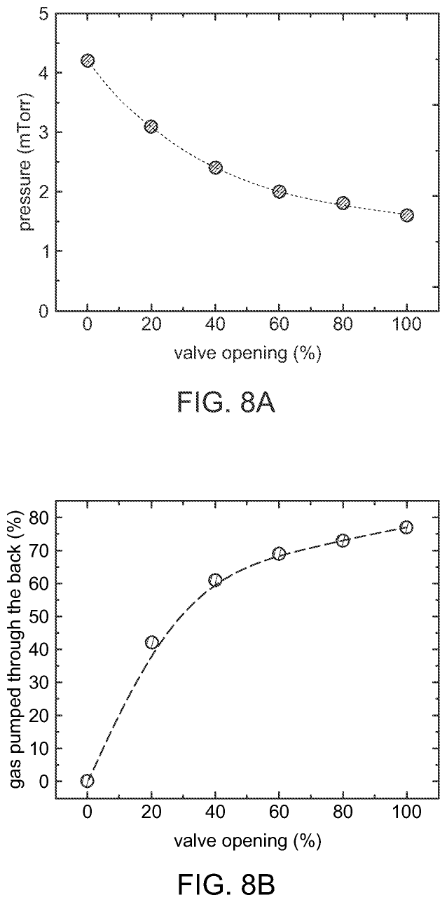

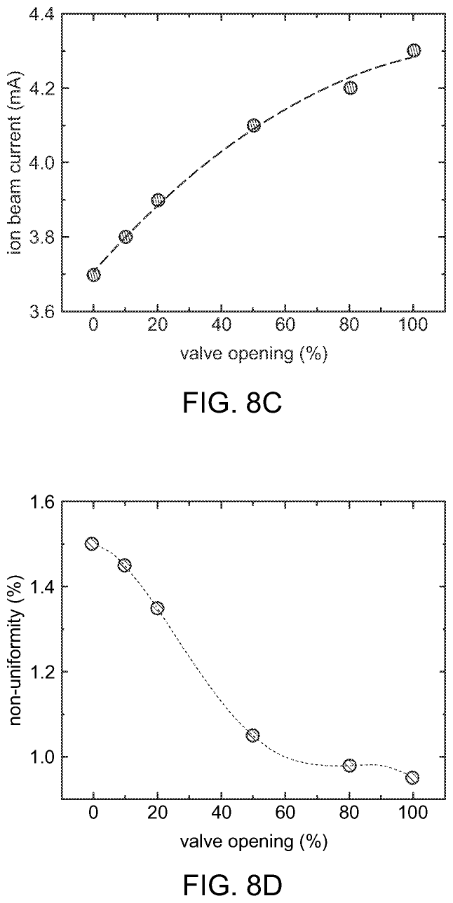

According to various embodiments of the disclosure, a valve controller 332 may be used to vary the opening of a valve 330 and thus control vacuum conductance and other properties of a processing system. Turning to FIG. 8A there is shown a graph that depicts plasma chamber pressure as a function of valve opening under the following scenario: the gas flow rate is 20 sccm. As depicted, the pressure can be varied from 4.2 mTorr (valve closed) to 1.7 mTorr (valve fully open). FIG. 8B shows the dependency of the amount of gas pumped through the residence time tuning assembly, meaning a pumping duct, such as pumping duct 124, shown as a function of valve opening percent. As can be seen, back pumping through a pumping duct 124 is very effective: half of the gas pumping occurs through the back for a valve opening of just 35%.

This behavior shows that substrate processing, such as substrate etching, may be readily controlled over a wide range using valve control of a residence time tuning assembly of the present embodiments. By way of further explanation, for etching processes, such as reactive ion beam etching of a surface layer or structure, a synergistic effect of ion bombardment and chemical reactivity of the radicals produced in a plasma is generally understood to be key to etching the substrate material. When bombarding the substrate surface ion generate dangling bonds in the superficial mixing layer, and then, by filling those bonds, radicals form volatile compounds which compounds are subsequently pumped away. As a result, the etch process characteristics are determined by the relative fluxes of ions and radicals arriving at the substrate surface. Too few ions result in a “radical excess” regime where not enough dangling bonds are generated. Conversely, too few radicals result in a “radical starvation” regime, where, although many dangling bonds are generated, not enough radicals are present to combine and form volatile compounds and advance the etch front. The result of the interplay of these two distinct mechanisms is that there is an optimal ratio between the flux of radicals and the flux of ions arriving at the substrate where the etch rate is maximal. The change in relative gas pumping through a pumping duct 124 affords the ability to change the gas species residence time and therefore the degree of radical and polymeric species formation. Polymeric species are needed to prevent etching of sidewalls by deposition of passivation polymeric films and thus helping to propagate the etching front toward the bottom of the trench. These polymeric films are formed by plasma polymerization of specific monomers that are part of the gaseous mixture fed into the plasma chamber, such as CHₓF_{y}. Conversely, an unduly long residence time will lead to high fractionation of the parent monomer resulting in lower deposition rate of passivation layer. Thus, there is a sensitive equilibrium between etching and polymerizing species, which equilibrium is to be maintained in the plasma. This equilibrium is driven by the length of residence time. Therefore the provision of a residence time tuning assembly in the present embodiments may afford more ability to define an optimum condition for etching of an extracted ion beam.

Moreover, as noted, by adjusting residence time, a residence time tuning assembly of the present embodiments may also affect ionization and related process features, such as beam current. Turning to FIG. 8C, there is shown a graph depicting the amount of beam current as a function of valve opening for a valve 330, according to embodiments of the disclosure. In the example shown, the beam current increases by 15% from fully closed valve to fully open. The present inventors have also discovered unexpectedly that beam non-uniformity may be decreased, in other words, beam uniformity increased, by approximately 35% by opening the valve to 60% or greater. This behavior is shown in FIG. 8D—and is a result of decreased pressure in the chamber which decrease favors gas diffusion and thus uniformization of the plasma.

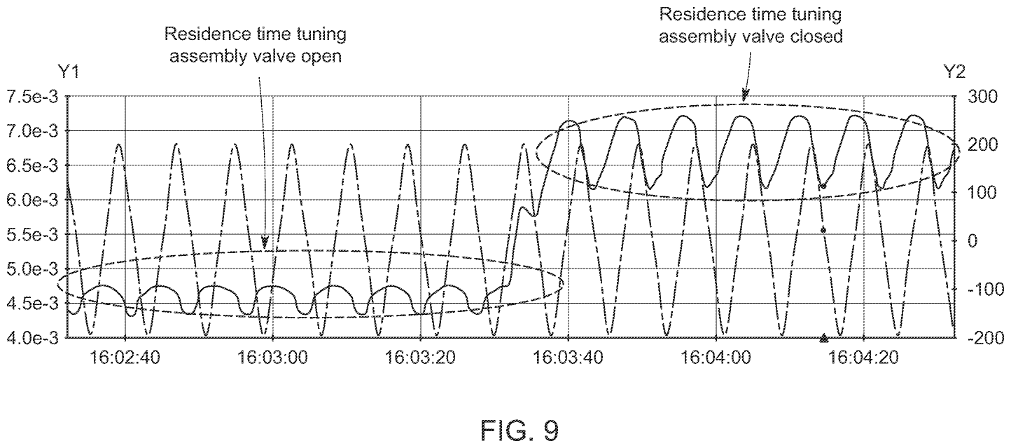

Another advantage afforded by the present embodiments is the ability to reduce pressure fluctuations during reactive ion beam processing of a substrate. In accordance with some embodiments, and with reference to FIG. 1B, during ion beam processing a substrate 108 may be scanned along a Y-direction so that an entirety of the substrate 108 may be exposed to the ion beam 130, though the ion beam 130 is relatively narrower than the substrate 108 along the Y-direction. During the scanning of the substrate 108, repeatedly back and forth along the Y-axis, temporal pressure fluctuations within the plasma chamber have been observed, as shown in FIG. 9. In this figure, the gas pressure and the position of the substrate center are shown as a function of time for a processing apparatus arranged with a plasma chamber 102, where a repeated, uniform pattern is observed. The experimental conditions for the plasma chamber 102 are an overall gas flow of 30 sccm, with a Z-gap between extraction aperture and substrate of 7 mm. The right half of the graph depicts the behavior where no residence time tuning assembly is used, such as having the valve 330 closed. In this scenario, the pressure in the plasma chamber varies between 6.1 mTorr and 7.2 mTorr. The left half of the graph depicts the case where a valve 330 is partially opened to set a nominal pressure of 4.6 mTorr in a static substrate condition. During scanning of the substrate, the pressure varies between 4.3 mTorr and 4.8 mTorr, a much narrower variation range in plasma chamber pressure as opposed to the case where a residence time tuning assembly is not used.

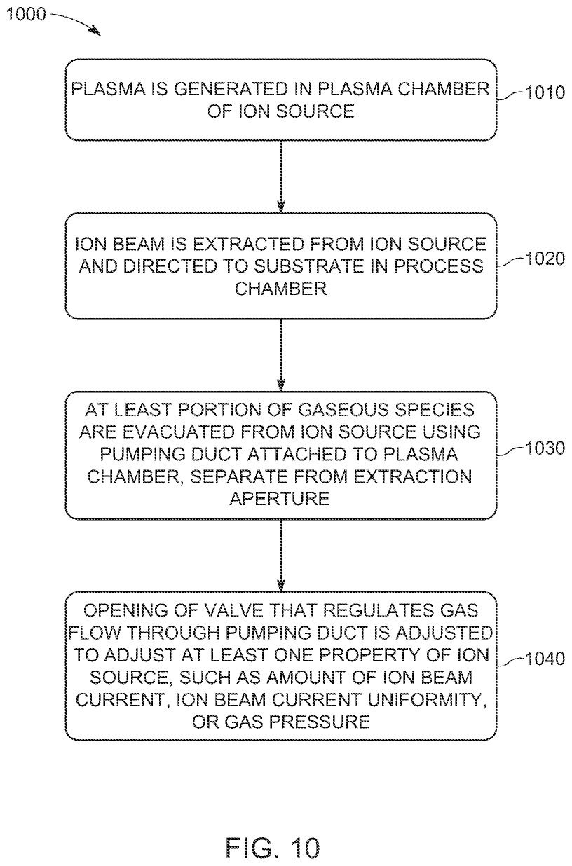

FIG. 10 depicts an exemplary process flow 1000. At block 1010, a plasma is generated in a plasma chamber of an ion source. The ion source may be any suitable ion source based upon plasmas as known in the art. At block 1020, an ion beam is extracted from the ion source and directed to a substrate in a process chamber. In some embodiments, an extraction aperture may be provided along a side of the ion source to extract the ion beam. In particular embodiments, the ion extraction aperture may have an elongated shape to define an ion beam characterized by an elongated cross-section, forming a so-called ribbon beam. In some embodiments a beam blocker may be provided next to the extraction aperture to partition the ion beam into a pair of ion beamlets.

At block 1030, at least a portion of the gaseous species are evacuated from the ion source using pumping duct attached to the plasma chamber, separate from the extraction aperture. As such, the use of the pumping duct may increase residence time of gaseous species in the plasma chamber on average.

At block 1040, the amount of opening in a valve that regulates gas flow through the pumping duct is adjusted to adjust at least one property of the ion source, such as the amount of ion beam current, ion beam current uniformity, or gas pressure.

In view of the above, the present disclosure provides at least the following advantages: i) it is possible to independently control the gas flow rate and gas pressure. In other words, the gas flow rate may be adjusted while maintain the same ion source gas pressure by adjusting a valve of a pumping port of a residence time tuning assembly. Moreover, the gas residence time may implicitly be independently adjusted by adjusting the same valve, while not having to change other processing system parameters, such as gas pumping speed, Z-gap, and so forth.

While certain embodiments of the disclosure have been described herein, the disclosure is not limited thereto, as the disclosure is as broad in scope as the art will allow and the specification may be read likewise. Therefore, the above description are not to be construed as limiting. Those skilled in the art will envision such modifications within the scope and spirit of the claims appended hereto.

1. A plasma processing apparatus, comprising:
a plasma chamber, to define a plasma therein;
an extraction aperture, arranged along a first side of the plasma chamber, the extraction aperture to define an ion beam extracted therethrough; and
a residence time tuning assembly, coupled to a portion of the plasma chamber, different from the first side,
wherein the residence time tuning assembly comprises a pumping duct, connected to the plasma chamber on a first end, and defining a pumping path for extracting a gaseous species directly from the plasma chamber, separately from the extraction aperture.

2. The plasma processing apparatus of claim 1, wherein the residence time tuning assembly further comprises a bellows, arranged along a portion of the pumping duct.

3. The plasma processing apparatus of claim 1, the residence time tuning assembly further comprising a valve, arranged between a first end of the pumping duct and a second end of the pumping duct, and a valve controller, arranged to vary gas pressure in the plasma chamber by adjusting the valve.

4. The plasma processing apparatus of claim 1, wherein the pumping duct is a first pumping duct, defining a first pumping path, the residence time tuning assembly further comprising a second pumping duct, having a near end connected to the plasma chamber, and defining a second pumping path for extracting the gaseous species directly from the plasma chamber.

5. The plasma processing apparatus of claim 1, the residence time tuning assembly further comprising a back pump, connected to a second end of the pumping duct.

6. The plasma processing apparatus of claim 1, wherein the extraction aperture is arranged along a side of a process chamber, and wherein the pumping duct is directly connected to the process chamber on a second end.

7. The plasma processing apparatus of claim 6, wherein the pumping duct comprises:
a first elbow portion, directly connected to the plasma chamber;
a bellows, connected to the first elbow portion; and
a second elbow portion, connected to the bellows and to the process chamber.

8. The plasma processing apparatus of claim 1, wherein the pumping duct is arranged along a portion of the plasma chamber, opposite to the extraction aperture.

9. A plasma processing system, comprising:
a plasma chamber, to define a plasma therein;
a process chamber, arranged along a side of the plasma chamber;
an extraction aperture, arranged between the plasma chamber, and process chamber, the extraction aperture to define an ion beam extracted therethrough; and
a residence time tuning assembly, coupled to a portion of the plasma chamber,
wherein the residence time tuning assembly comprises a pumping duct, connected to the plasma chamber on a first end, and defining a pumping path for extracting a gaseous species directly from the plasma chamber, separately from the extraction aperture.

10. The plasma processing system of claim 9, wherein the residence time tuning assembly further comprises a bellows, arranged along a portion of the pumping duct.

11. The plasma processing system of claim 9, the residence time tuning assembly further comprising a valve, arranged between a first end of the pumping duct and a second end of the pumping duct, and a valve controller, arranged to vary gas pressure in the plasma chamber by adjusting the valve.

12. The plasma processing system of claim 9, wherein the pumping duct is a first pumping duct, defining a first pumping path, the residence time tuning assembly further comprising a second pumping duct, having a near end connected to the plasma chamber, and defining a second pumping path for extracting the gaseous species directly from the plasma chamber.

13. The plasma processing system of claim 9, the residence time tuning assembly further comprising a back pump, connected to a second end of the pumping duct.

14. The plasma processing system of claim 9, wherein the pumping duct is connected to the process chamber on a second end.

15. The plasma processing system of claim 9, wherein the pumping duct comprises:
a first elbow portion, directly connected to the plasma chamber;
a bellows, connected to the first elbow portion; and
a second elbow portion, connected to the bellows and to the process chamber.

16. The plasma processing system of claim 9, wherein the pumping duct is arranged along a portion of the plasma chamber, opposite to the extraction aperture.

17. The plasma processing system of claim 9, wherein the process chamber further comprises a substrate platen, arranged opposite to the extraction aperture, and defining a separation between the extraction aperture and a substrate, disposed on the substrate platen, wherein the substrate platen is movable to adjust the separation.

18. A method of operating an ion source, comprising:
forming a plasma in a plasma chamber of the ion source using gaseous species;
extracting an ion beam through an extraction aperture disposed along a side of the ion source; and
pumping at least a portion of the gaseous species from the plasma chamber using a residence time tuning assembly that comprises a pumping duct, connected to the plasma chamber on a first end, and defines a pumping path for extracting the gaseous species directly from the plasma chamber, separately from the extraction aperture.

19. The method of claim 18,
wherein the extraction aperture defines a border between the plasma chamber and a process chamber,
wherein a system pump is connected to the process chamber for evacuating gas the process chamber, and
wherein the pumping duct is connected on a second end to the process chamber.

20. The method of claim 18, further comprising:
providing a valve to regulate flow of gas through the pumping duct; and
adjusting an opening of the valve to adjust at least one property of the ion source, the at least one property including: beam current, beam uniformity, and gas pressure in the plasma chamber.
